(19) United States
(12) Patent Application Publication
(10) Pub. No.: US 2010/0052037 A1
(43) Pub. Date: Mar. 4, 2010

(54) Charge-trapping engineered flash non-volatile memory

(76) Inventor: Albert Chin, Taipei City (TW)

Correspondence Address: Albert, CHIN, P.O. BOX 46-563 Taipei, Taipei City 10499, 104, TW

(21) Appl. No.: 12/229,860

(22) Filed: Aug. 28, 2008

(51) Int. Cl. H01L 29/792

(52) U.S. Cl. 257/324; 257/E29.309

(57) ABSTRACT

This invention proposes a charge-trapping-engineered flash (CTEF) non-volatile memory (NVM) of electrode-[blocking oxide]-[trapping_{—}1-trapping_{—}2]-[tunneling oxide]-semiconductor. Dual trapping layers of higher energy bandgap (E_{G}) trapping_{—}1 and deeper-trapping-energy smaller E_{G} trapping_{—}2 dual blocking dielectrics and dual tunneling dielectrics are used to improve the retention characteristics at scaled equivalent-oxide-thickness (EOT).

### BACKGROUND OF THE INVENTION

1. Field of the Invention

The invention relates to a Charge-Trapping Engineered Flash (CTEF) Non-Volatile Memory (NVM) device. More particularly, the invention relates to a new CTEF NVM of electrode-[blocking oxide]-[trapping_1-trapping_2]-[tunneling oxide]-semiconductor device, with dual trapping layers for larger memory window and better stored charge retention at high temperatures.

2. Description of the Related Art

According to International Technology Roadmap for Semiconductors (ITRS) (herein after refer to as prior art [1]), continuous down-scaling the [poly-Si or metal]-oxide-Si₃N₄-oxide-semiconductor [SONOS or MONOS] non-volatile memory (NVM) (herein after refer to as prior art [2]-[4]) is required to suppress the unwanted short channel effect and leakage current. FIG. 1 shows the energy band diagram and device structure of the conventional MONOS NVM. During program, a voltage is applied to gate electrode 14 and the carriers are injected from semiconductor substrate 10 over the tunneling oxide 11 into Si₃N₄ charge-trapping layer 12. The charges are stored in Si₃N₄ charge-trapping layer 12 and confined within blocking oxide 13 and tunneling oxide 11 due to smaller energy bandgap (E_{G}) in Si₃N₄ charge-trapping layer 12. During erase, the stored charges in Si₃N₄ charge-trapping layer 12 are lowered by applying a different voltage at gate electrode 14. The blocking oxide 13 is usually SiO₂ or SiO₂/Si₃N₄/SiO₂ and tunneling oxide 11 is usually SiO₂. The down-scaling blocking oxide 13 and tunneling oxide 11 can be realized by using high dielectric constant (high-κ) materials that give small equivalent oxide thickness (EOT) by t_{dielectric}×κ_{SiO2}/κ_{dielectric}, where the t_{dielectric}, κ_{dielectric} and κ_{SiO2 are the high-κ layer thickness, high-κ value and SiO}₂ dielectric constant respectively. However, scaling down the Si₃N₄ charge-trapping layer 12 is especially challenging since the charge trapping capability is worse at thinner Si₃N₄. The high temperature retention also gets worse at thin Si₃N₄, due to the higher trap energy in oxide/Si₃N₄/oxide, arising from quantum confinement. The retention may be improved by using a thicker tunneling and blocking layers, but this yields low erase speeds (10˜100 ms) and opposite to scaling trend. Such retention and erase-speed trade-off is a fundamental limitation of NVM. We addressed this previously using deep trapping energy Al(Ga)N or HfON layer in a MONOS device, rather than Si₃N₄, where much improved data retention were obtained and also listed in ITRS [1]. However, the conventional Si₃N₄ has the important advantage of better trapping capability than high-κ Al(Ga)N or HfON for desired larger memory window.

### SUMMARY OF THE INVENTION

To overcome the drawbacks of the prior arts, in this invention we report a charge-tapping-engineered flash (CTEF) NVM device. The energy band diagram and device structure is shown in FIG. 2, which has highly scaled dual trapping layers of large E_{G} trapping_1 23 and deep trapping-energy small E_{G} trapping_2 22, top blocking oxide 24 and bottom tunneling oxide 21, and still achieves good retention and large memory window. During program, a voltage is applied to gate electrode 25 to cause carriers generation in semiconductor 20 and charge injection into dual trapping layers of large E_{G} trapping_1 23 and deep trapping-energy small E_{G} trapping_2 22. During erase, a different voltage is applied to gate electrode 25 to lower the charge storage inside dual trapping layers of trapping_1 23 and trapping_2 22.

Instead of single blocking layer and tunneling layer depicted in FIG. 2, dual dielectrics of 36 and 35 for top blocking layers and 32 and 31 for bottom tunneling layers can be used in this CTEF NVM device as shown in FIG. 3 for better memory performance. Besides, dual charge-trapping layers of large E_{G} trapping_1 34 and deep trapping-energy small E_{G} trapping_2 33 are used. During program, a voltage is applied to gate electrode 37 to cause carriers generation in semiconductor 30 and charge injection into dual trapping layers of large E_{G} trapping_1 34 and deep trapping-energy small E_{G} trapping_2 33. During erase, a different voltage is applied to gate electrode 37 to lower the charge storage inside dual trapping layers of trapping_1 34 and trapping_2 33.

To implement this device, we use the TaN top electrode, top dual dielectric blocking layers of 5 nm-SiO₂/5 nm-LaAlO₃ (1 nm-EOT), dual trapping layers of 5 nm-Si₃N₄/5 nm-HfON (0.9 nm-EOT), bottom dual dielectric tunneling layers of 2.5 nm-LaAlO₃ (0.5 nm-EOT)/2.5 nm-SiO₂ and Si substrate as an example. Other combination of trapping layers such as Si₃N₄, AlN, Al(Ga)N, HfON, ZrON, TiON AlON, Al(Ga)ON, and dual dielectrics top blocking or bottom tunneling layers of SiO₂, SiN, SiON, Al₂O₃, HfSiO(N), HfZrO(N), HfLaO(N), HfAlO(N), LaAlO₃, and the combination of these dielectrics can also be implemented in this CTEF NVM device. The CTEF device was made by depositing the gate stack of TaN—[SiO₂—LaAlO₃]—[Si₃N₄—HfON]—[LaAlO₃—SiO₂] on Si substrate, standard gate patterning and etching, a self-aligned 25 keV phosphorus ion implantation at 5×10¹⁵ cm⁻² and rapid thermal annealing (RTA) to activate the implanted dopants at source-drain. The fabricated CTEF device, at 150° C. and ±16V program/erase (P/E), showed a fast P/E speed of 100 μs, large initial threshold voltage change (ΔVₜₕ) memory window of 5.6V and extrapolated 10-year retention window of 3.8V simultaneously. These results are much better than those of control charge-tapping-flash (CTF) device without the extra 0.9 nm EOT HfON but with the same other layers, which had a smaller initial 3.3V memory window and poorer extrapolated 10-year retention of 1.7V The improved memory window in CTEF is due to the good trapping capability of combined shallow- and deep-trapping energy Si₃N₄—HfON layers with only extra 0.9 nm EOT in HfON. The much better 150° C. retention in CTEF devices is attributed to the trapped shallow-energy charges in thin Si₃N₄ relaxing into deeper energy HfON shown in FIG. 3 rather than leak out. Large 10⁵-cycled window of 4.9V was also measured. These results compare well with other data [2]-[4] in Table 1, with better 150° C. retention, larger memory window and higher speed.

TABLE 1
Comparisons of P/E voltage, speed, initial ΔVₜₕ memory window,
extrapolated for 10-year retention window at 85 and 150° C. and endurance.

| | | | ΔVₜₕ (V) for | ΔVₜₕ (V) for | |
|---|---|---|---|---|---|
| | P/E conditions | Initial | 10-year | 10-year | |
| | for retention | ΔVₜₕ | retention | retention @ | ΔVₜₕ (V) |
| | & cycling | (V) | @ 85° C. | 150° C. | @Cycles |
| This Invention | 16 V 100 μs/ | 5.6 | 4.1 | 3.8 | 4.9@10⁵ |
| (CTEF) | −16 V 100 μs | | | | |
| This Invention | 16 V 100 μs/ | 3.3 | 2.0 | 1.7 | — |
| (single-trapping Si₃N₄) | −16 V 100 μs | | | | |
| TANOS [2] | 13.5 V 100 μs/ | 4.4 | 2.07 | No data | 4@10⁵ |
| SiO₂/Si₃N₄/Al₂O₃/TaN | −13 V 10 ms | | | | |
| Tri-gate [3] | 11.5 V 3 ms/ | 1.2 | 1.1 | No data | 1.5@10⁴ |
| SiO₂/Si₃N₄/SiO₂ | −11.5 V 100 ms | | (@25° C.) | | |
| FinFET [4] | 13 V 10 μs/ | 4.5 | 2.4 | No data | 3.5@10⁴ |
| SiO₂/Si₃N₄/SiO₂ | −12 V 1 ms | | | | |

### DETAIL OF PRIOR ARTS

[1] International Technology Roadmap for Semiconductors (ITRS), 2005. [Online]. Available: www.itrs.net
[2] C. H. Lee, K. I. Choi, M. K. Cho, Y. H. Song, K. C. Park, and K. Kim, “A novel SONOS structure of SiO₂/SiN/Al₂O₃ with TaN metal gate for multi-giga bit flash memories,” in IEDM Tech. Dig., 2003, pp. 613-616.
[3] M. Specht, R. Kommling, L. Dreeskornfeld, W. Weber, F. Hofmann, D. Alvarez, J. Kretz, R. J. Luyken, W. Rosner, H. Reisinger, E. Landgraf, T. Schulz, J. Hartwich, M. Stadele, V. Klandievski, E. Hartmann, and L. Risch, “Sub-40 nm tri-gate charge trapping nonvolatile memory cells for high-density applications,” in Symp. on VLSI Tech. Dig., 2004, pp. 244-245.
[4] C. W. Oh, S. D. Suk, Y. K. Lee, S. K. Sung, J.-D. Choe, S.-Y. Lee, D. U. Choi, K. H. Yeo, M. S. Kim, S.-M. Kim, M. Li, S. H. Kim, E.-J. Yoon, D.-W. Kim, D. Park, K. Kim, and B.-I. Ryu, “Damascence gate FinFET SONOS memory implemented on bulk silicon wafer,” in IEDM Tech. Dig., 2004, pp. 893-896.

### BRIEF DESCRIPTION OF THE DRAWINGS

FIG. 1. Schematic energy band diagram of conventional metal-oxide-Si₃N₄-oxide-semiconductor (MONOS) non-volatile memory (NVM).

FIG. 2. Schematic energy band diagram of charge-trapping-engineered flash (CTEF) NVM device of electrode-[blocking oxide]-[trapping_1-trapping_2]-[tunneling oxide]-semiconductor. Here both large E_{G} trapping_1 and deep-trapping small E_{G} trapping_2 are used for charge storage.

FIG. 3. Schematic energy band diagram of electrode-[dual blocking oxides]-[trapping_1-trapping_2]-[dual tunneling oxides]-semiconductor CTEF NVM device. The top dual dielectrics blocking oxides and bottom dual tunneling oxides are used for enhanced confinement of stored charges. The E_{G} for dual tunneling oxides are different to form a conduction band discontinuity (ΔE_{C}) and a valence band discontinuity (ΔE_{V}) for faster program and erase by electron and hole tunneling, respectively.

FIG. 4. Gate current density and gate voltage (J_{g}-V_{g}) characteristics for CTEF devices.

FIG. 5. Gate capacitance and gate voltage (C-V) hysteresis for CTEF devices.

FIG. 6. Program characteristics for different voltages & times of CTEF devices.

FIG. 7. Erase characteristics for different voltages & times of CTEF devices.

FIG. 8. Program characteristics for different voltages & times of control CTF devices with the same single Si₃N₄ trapping, dual blocking oxides and tunneling oxides but without extra 0.9 nm EOT HfON trapping layer.

FIG. 9. Erase characteristics for different voltages & times of control CTF devices with the same single Si₃N₄ trapping, dual blocking oxides and tunneling oxides but without extra 0.9 nm EOT HfON trapping layer.

FIG. 10. Retention characteristics of CTEF devices at 25° C.

FIG. 11. Retention characteristics of CTEF devices at 85° C.

FIG. 12. Retention characteristics of CTEF devices at 125° C.

FIG. 13. Retention characteristics at 25° C., 85° C. and 150° C. of control CTF devices with the same single Si₃N₄ trapping, dual blocking oxides and tunneling oxides but without extra 0.9 nm EOT HfON trapping layer.

FIG. 14. Endurance characteristics of CTEF devices.

FIG. 15. 10³ P/E cycled retention data of CTEF devices.

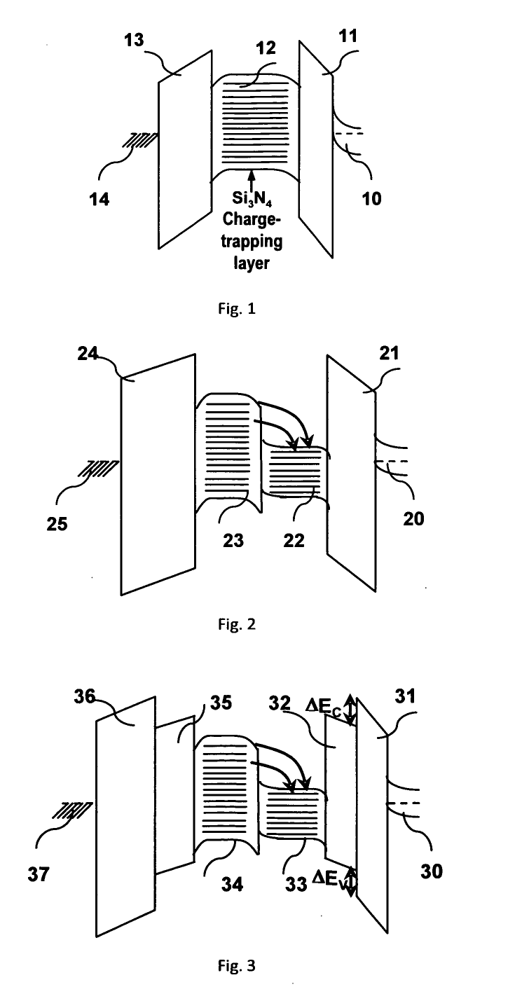

### DETAILED DESCRIPTION OF THE PREFERRED EMBODIMENT

For the best understanding of this invention, please refer to the following detailed description of the preferred embodiments and the accompanying drawings, wherein:

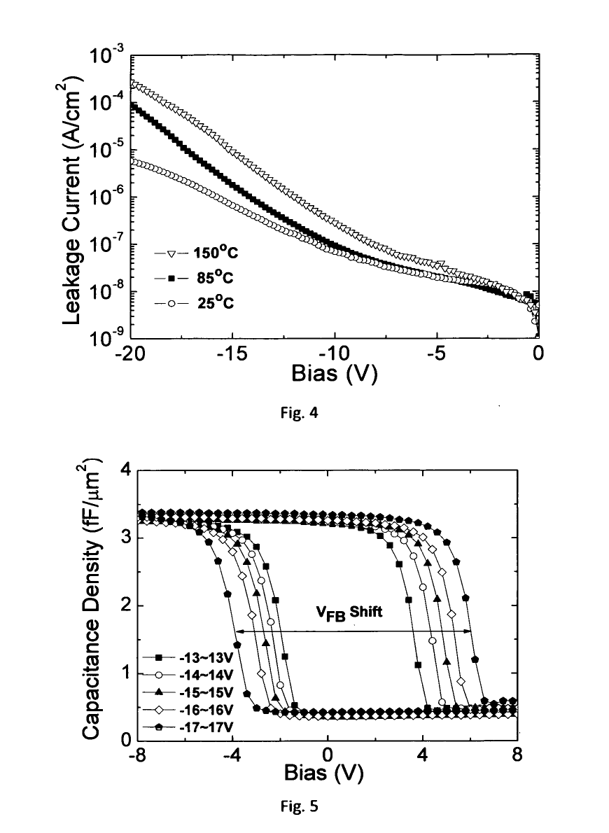

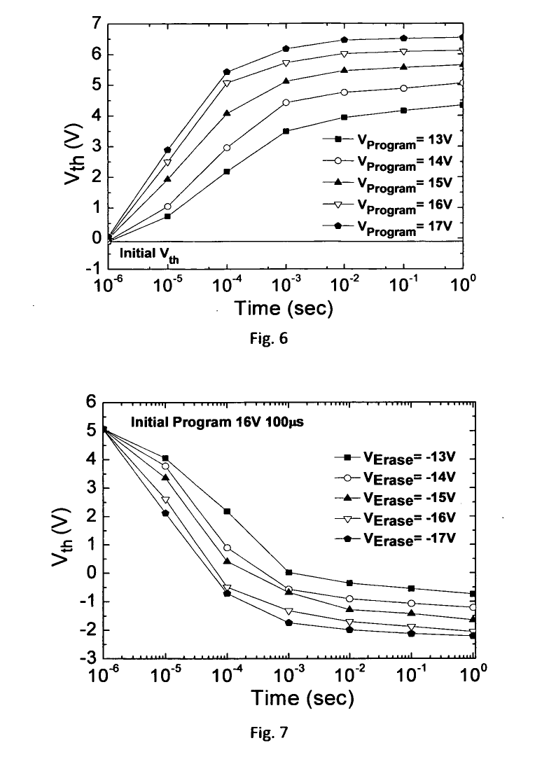

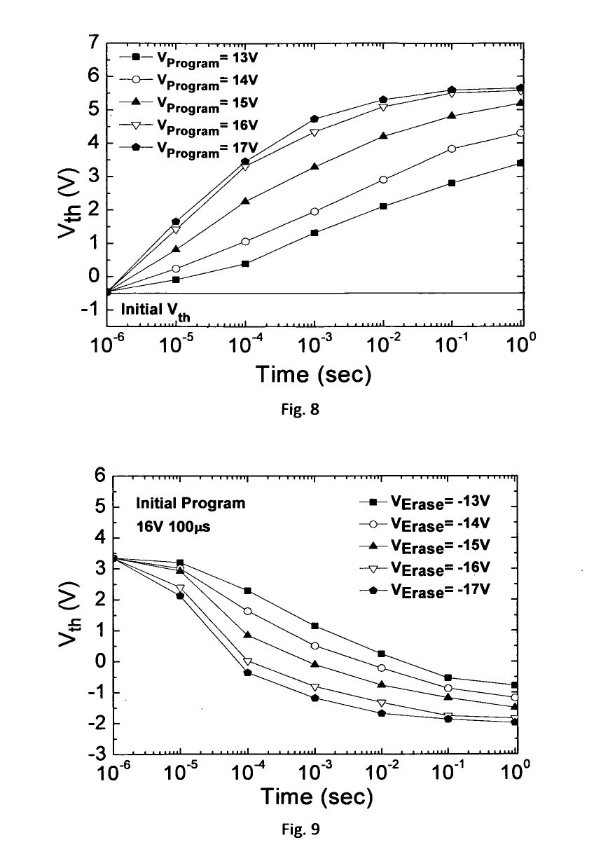

In view of the drawbacks of the prior arts, this invention proposes a CTEF NVM for better scalability, larger memory window and better high temperature retention under fast program/erase condition. The using LaAlO₃—SiO₂ for dual tunneling oxides 32-31 permits faster P/E, which arises from the existing ΔE_{C} and ΔE_{V} in LaAlO₃—SiO₂ interface for better electron and hole tunneling during program and erase respectively. The larger physical thickness using high-κ oxides of 35 and 32 improve the retention. The adding deep trapping energy HfON, with only extra 0.9 nm EOT, in the Si₃N₄—HfON of dual trapping layers 34-33 of CTEF device further improves the retention with additional ΔE_{C} charge confinement to high-κ LaAlO₃ tunneling oxide 32. The using SiO₂—LaAlO₃ for dual blocking oxides 36-35 is also important for retention due to the physically thick high-κ LaAlO₃ and low defect SiO₂ with overall small EOT. FIG. 4 shows the erase J-V characteristics and small leakage seen up to 150° C. Very large C-V hysteresis of 6.6˜9.9V was found under ±13˜17V sweep in FIG. 5, which shows the strong charge-trapping capability even in the highly scaled 5 nm Si₃N₄ with only 0.9 nm EOT HfON. FIGS. 6-7 show the Vₜₕ shift as functions of program and erase. A fast P/E time of 100 μs was measured at ±16V, along with a large ΔVₜₕ, giving a memory window of 5.6V in CTEF device. For comparison, the program and erase characteristics of control CTF device without extra 0.9 nm EOT HfON are shown in FIGS. 8-9. The ΔVₜₕ is smaller for both the program and erase cases, along with a small memory window of 3.3V at ±16V 100 μs P/E.

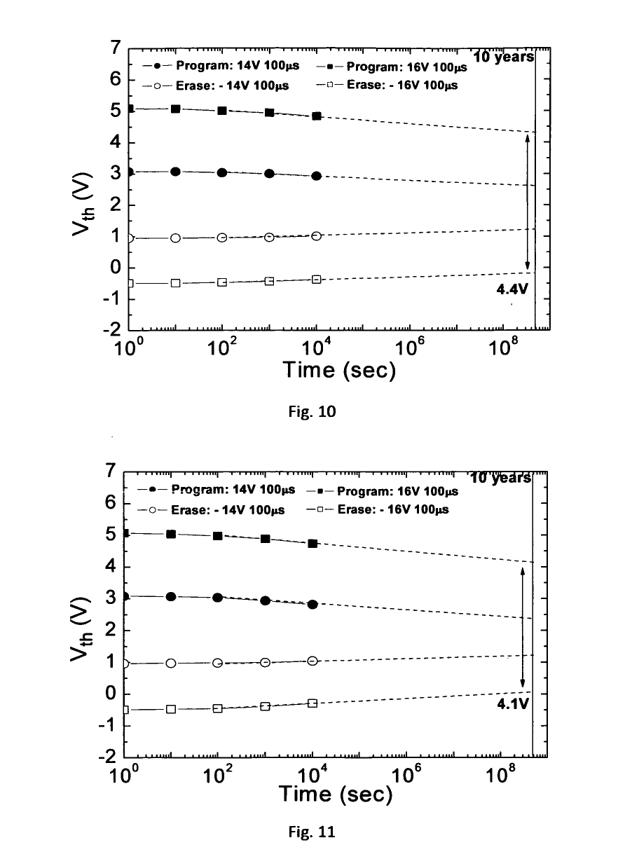

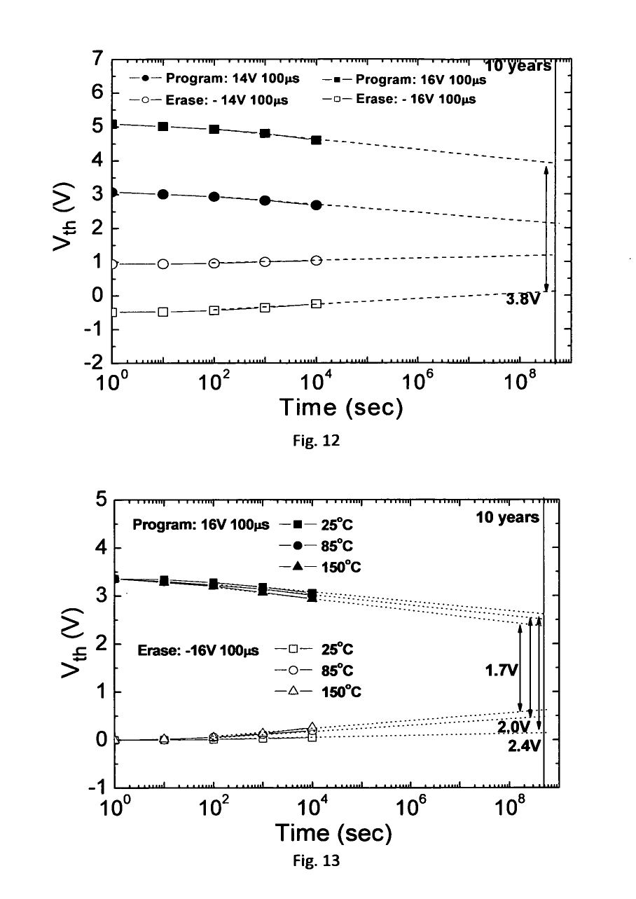

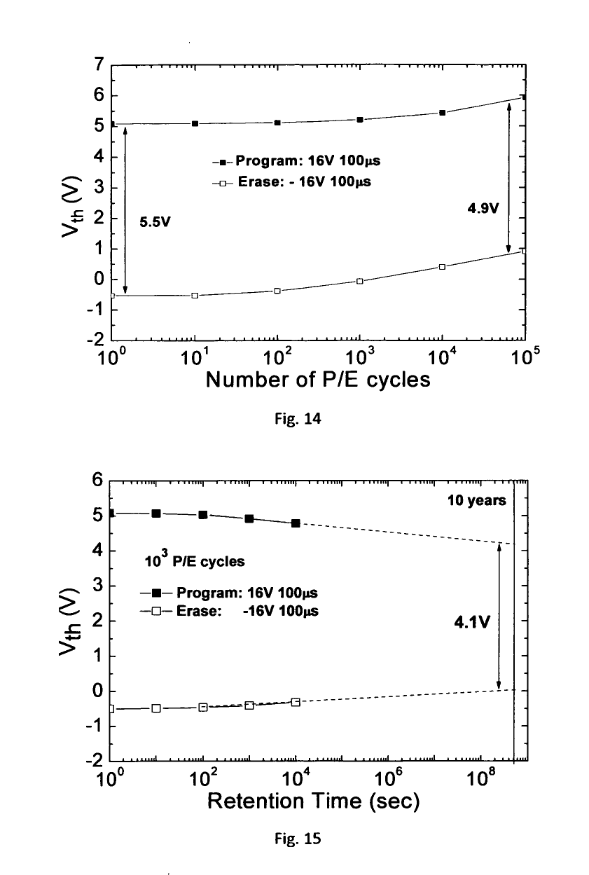

The retention data for CTEF at 25, 85 and 150° C. are displayed in FIGS. 10-12. The extrapolated 10-year memory window decreases with increasing temperature. At 150° C., an initial ΔVₜₕ of 5.6V and 10-year window of 3.8V were measured at 100 μs and ±16V P/E. The 10²˜10³ times faster erase speed, compared with the conventional SONOS or MONOS, is due to the lower hole tunneling energy barrier, ΔE_{V}, between the LaAlO₃ and SiO₂ in the CTEF devices. This design is possible due to the existing ΔE_{V} and ΔE_{C} between HfON trapping layer and high-κ LaAlO₃ tunneling layer for both fast hole tunneling erase and trapped electron retention, respectively. Meanwhile good retention is also maintained by physically thicker double LaAlO₃—SiO₂ confinement and stored charges relaxing from shallow-trapping-energy Si₃N₄ into deep energy HfON as shown in FIG. 3. Such large 10-year window enables 4 logic levels, as in multi-level cells (MLC), where a large enough difference of average ˜1.3V exists for each level at 150° C. For comparison, the retention data of control CTF device with single-Si₃N₄-trapping dual-oxide-barriers are shown in FIG. 13. A 3.3V initial ΔVₜₕ and 1.7V 10-year extrapolated memory window were measured at the same 150° C., significantly worse than those for the CTEF device. We also found good endurance: a large 10⁵-cycled memory window of 4.9V and 10³-cycled 10-year retention window of 4.1V, at ±16V 100 μis P/E as shown in FIGS. 14-15. Such good endurance is due to the fast P/E speed produces less stress and trap-generation in the 3 nm EOT LaAlO₃—SiO₂ tunneling oxide. Table 1 compares and summarizes the memory data. Our CTEF device data, with highly scaled 5 nm thin Si₃N₄ and 0.9 nm EOT HfON trapping layers, compares well with that for other devices [2]-[4], with larger memory window, better 150° C. retention and higher speed.

Although a preferred embodiment of the invention has been described for purposes of illustration, it is understood that various changes and modifications to the described embodiment can be carried out without departing from the scope and the spirit of the invention as disclosed in the appended claims.

What is claimed is:

1. A charge-trapping-engineered flash (CTEF) non-volatile memory device has structure of electrode-[blocking oxide]-[trapping_1-trapping_2]-[tunneling oxide]-semiconductor, wherein large energy bandgap (E_{G}) trapping_1 layer and deep-trapping small E_{G} trapping_2 layer are used for charge storage, and single dielectric layer or dual dielectric layers are used for blocking oxide and tunneling oxide.

2. The CTEF non-volatile memory device according to claim 1, wherein the dual trapping layers of trapping_1 and trapping_2 can be Si₃N₄, AlN, Al(Ga)N, HfON, ZrON, TiON, AlON, Al(Ga)ON and their combinations of these dielectrics with large E_{G} trappings_layer and deep-trapping small E_{G} trapping_2 layer.

3. The CTEF non-volatile memory device according to claim 1, wherein the single dielectric layer or dual dielectrics layers for blocking oxide and tunneling oxide can be SiO₂, SiN, SiON, Al₂O₃, HfSiO(N), HfZrO(N), HfLaO(N), HfAlO(N), LaAlO₃, and the combination of these dielectrics.

4. The CTEF non-volatile memory device according to claim 1, wherein the case of dual dielectrics for tunneling oxide have different E_{G} and form a conduction band discontinuity (ΔE_{C}) and a valance band discontinuity (ΔE_{V}) for faster program and erase by better electron and hole tunneling, respectively.

5. The CTEF non-volatile memory device according to claim 1, wherein the case of dual dielectrics for blocking oxide have different E_{G} between them

6. The CTEF non-volatile memory device according to claim 1, wherein the semiconductor can be single crystal or poly-crystal Si, SiGe, Ge, and organic semiconductors.

7. The CTEF non-volatile memory device according to claim 1, wherein the electrode can be metal, metal-nitride, doped poly-crystalline Si, SiGe, Ge, and organic semiconductors.
